(19) United States
(12) Patent Application Publication
(10) Pub. No.: US 2024/0321945 A1
(43) Pub. Date: Sep. 26, 2024

(54) CAPACITOR

(71) Applicants: Kabushiki Kaisha Toshiba, Tokyo (JP); Toshiba Electronic Devices & Storage Corporation, Tokyo (JP)

(72) Inventor: Tatsuya OHGURO, Kanazawa Ishikawa (JP)

(21) Appl. No.: 18/463,231

(22) Filed: Sep. 7, 2023

(30) Foreign Application Priority Data
Mar. 22, 2023 (JP) 2023-045928

(51) Int. Cl. H01G 4/08; H01G 4/228

(52) U.S. Cl. CPC H01L 28/91; H01G 4/08; H01G 4/228

(57) ABSTRACT

According to one embodiment, a capacitor includes a semiconductor substrate, an electrode layer extending from a surface of the semiconductor substrate into the semiconductor substrate and containing a metal silicide in the semiconductor substrate, a dielectric film provided between the electrode layer and the semiconductor substrate and electrically insulating the electrode layer from the semiconductor substrate, a first terminal connected to the electrode layer, and a second terminal connected to the semiconductor substrate.

### CROSS-REFERENCE TO RELATED APPLICATIONS

This application is based upon and claims the benefit of priority from Japanese Patent Application No. 2023-045928, filed on Mar. 22, 2023; the entire contents of which are incorporated herein by reference.

### FIELD

Embodiments relate to a capacitor.

### BACKGROUND

A capacitor disposed in an electronic circuit is required to have a small size and a high-frequency response.

### DESCRIPTION OF THE DRAWINGS

FIG. 1 is a schematic cross-sectional view showing a capacitor according to an embodiment.

FIG. 2 is a schematic plan view showing the capacitor according to the embodiment.

FIG. 3A is a schematic view showing characteristics of the capacitor according to the embodiment.

FIG. 3B is a schematic view showing characteristics of the capacitor according to the embodiment.

FIG. 4A is a schematic cross-sectional view showing a process for manufacturing the capacitor according to the embodiment.

FIG. 4B is a schematic cross-sectional view showing a process for manufacturing the capacitor according to the embodiment.

FIG. 4C is a schematic cross-sectional view showing a process for manufacturing the capacitor according to the embodiment.

FIG. 5A is a schematic cross-sectional view showing a process for manufacturing following FIG. 4.

FIG. 5B is a schematic cross-sectional view showing a process for manufacturing following FIG. 4.

FIG. 5C is a schematic cross-sectional view showing a process for manufacturing following FIG. 4.

FIG. 6 is a schematic cross-sectional view showing a capacitor according to a first variation of the embodiment.

FIG. 7 is a schematic cross-sectional view showing a capacitor according to a second variation of the embodiment.

FIG. 8 is a schematic plan view showing a capacitor according to a third variation of the embodiment.

FIG. 9A is a schematic cross-sectional view showing the dielectric films of the capacitor according to the embodiment.

FIG. 9B is a schematic cross-sectional view showing the dielectric films of the capacitor according to the embodiment.

### DETAILED DESCRIPTION

In general, according to one embodiment, a capacitor includes a semiconductor substrate, an electrode layer extending from a surface of the semiconductor substrate into the semiconductor substrate and containing a metal silicide in the semiconductor substrate, a dielectric film provided between the electrode layer and the semiconductor substrate and electrically insulating the electrode layer from the semiconductor substrate, a first terminal connected to the electrode layer, and a second terminal connected to the semiconductor substrate.

Hereinafter, an embodiment will be described with reference to the drawings. A detailed description of the same portion in the drawings attached with the same reference sign will be omitted as appropriate, and a different portion will be described. The drawings are schematic or conceptual. A relationship between a thickness and a width of each portion, a ratio of sizes between portions, and the like are not necessarily the same as the actual ones. Even if same portions are shown, dimensions and ratios may be shown differently from each other in the drawings.

Further, a disposition and a configuration of each part will be described using an X axis, a Y axis, and a Z axis shown in each drawing. The X axis, the Y axis, and the Z axis are orthogonal to one another and separately represent an X-direction, a Y-direction, and a Z-direction. The Z-direction may be described as an upper side, and an opposite direction of the Z-direction may be described as a lower side.

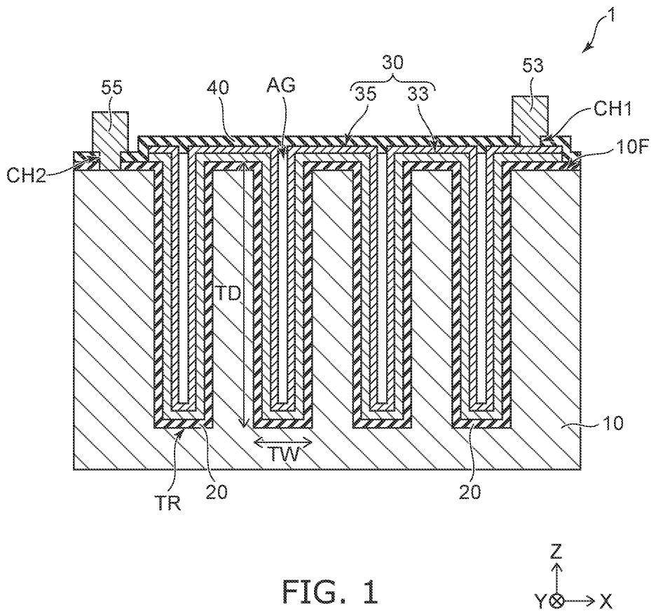

FIG. 1 is a schematic cross-sectional view showing a capacitor 1 according to an embodiment. The capacitor 1 is provided on a semiconductor substrate 10, for example, a silicon substrate. The capacitor 1 may be a single device or may be provided together with an integrated circuit on the semiconductor substrate 10.

As shown in FIG. 1, the capacitor 1 includes the semiconductor substrate 10, a dielectric film 20, an electrode layer 30, an insulating film 40, a first terminal 53, and a second terminal 55. The semiconductor substrate 10 is, for example, a low-resistance n-type silicon substrate. An n-type impurity concentration in the semiconductor substrate 10 is, for example, in a range of 1×1018 cm-3 to 1×1020 cm-3.

The semiconductor substrate 10 includes multiple trenches TR provided at a surface 10F side of the semiconductor substrate 10. Hereinafter, each of the trenches TR has a depth TD and a width TW. The trench TR is provided with a size that provides a predetermined static capacitance. An aspect ratio TD/TW of the trench TR is, for example, 50 or more, and preferably, for example, 100.

The dielectric film 20 is provided at the surface 10F side of the semiconductor substrate 10 and covers an inner surface of the trench TR. The dielectric film 20 includes, for example, at least one of a silicon oxide film and a silicon nitride film. The dielectric film 20 may be a high dielectric constant film containing aluminum oxide or hafnium oxide, a so-called high-k film.

The electrode layer 30 is provided on the dielectric film 20 and covers the inner surface of the trench TR. The electrode layer 30 is provided such that a gap AG is left inside the trench TR. The electrode layer 30 has, for example, an opening at the surface 10F side of the semiconductor substrate 10. The gap AG extends from the opening of the electrode layer 30 to a vicinity of a lower end of the trench TR at a bottom surface side. The dielectric film 20 and the electrode layer 30 are stacked on a bottom surface of the trench TR, and the electrode layer 30 is exposed at a lower end of the gap AG.

The electrode layer 30 includes, for example, a first conductive layer 33 and a second conductive layer 35. The first conductive layer 33 is, for example, conductive polysilicon. The second conductive layer 35 is a metal silicide. The second conductive layer 35 is, for example, nickel silicide (NiSi). The second conductive layer 35 is exposed on an inner surface of the gap AG.

The electrode layer 30 faces the semiconductor substrate 10 via the dielectric film 20 in the trench TR. The first conductive layer 33 is provided between the dielectric film 20 and the second conductive layer 35. The first conductive layer 33 faces the semiconductor substrate 10 via the dielectric film 20.

The insulating film 40 is provided on the electrode layer 30 at the surface 10F side of the semiconductor substrate 10. The insulating film 40 is, for example, a silicon nitride film. The insulating film 40 closes an opening of the electrode layer 30, and the gap AG is provided inside the trench TR.

The first terminal 53 is provided on the insulating film 40. The first terminal 53 is provided on the electrode layer 30 via the insulating film 40, and is connected to the electrode layer 30 via a contact hole CH1 provided in the insulating film 40. The first terminal 53 contains, for example, aluminum, and is electrically connected to the second conductive layer 35 of the electrode layer 30.

The second terminal 55 contains, for example, aluminum, and is provided on the insulating film 40. The insulating film 40 also covers a portion at the surface 10F side of the semiconductor substrate 10 where the electrode layer 30 is not provided. The dielectric film 20 extends, for example, between the semiconductor substrate 10 and the insulating film 40. The second terminal 55 is connected to the semiconductor substrate 10 via a contact hole CH2 provided in the dielectric film 20 and the insulating film 40.

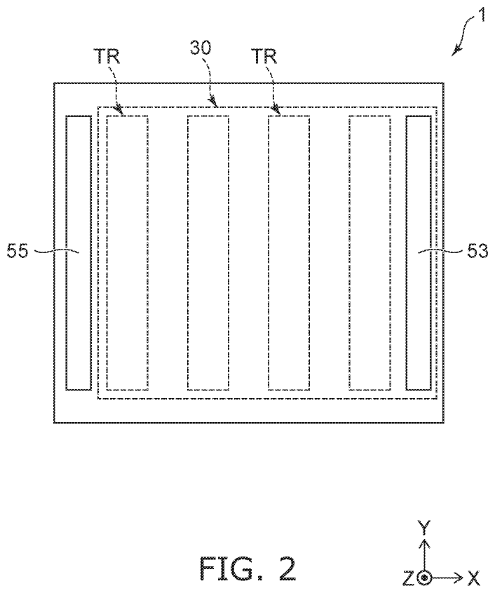

FIG. 2 is a schematic plan view showing the capacitor 1 according to the embodiment. FIG. 2 shows the first terminal 53 and the second terminal 55 provided on the insulating film 40. The first terminal 53 is positioned on the electrode layer 30.

As shown in FIG. 2, the multiple trenches TR each extend in the Y-direction and are aligned in the X-direction. The first terminal 53 and the second terminal 55 extend in the Y-direction. The multiple trenches TR are provided between the first terminal 53 and the second terminal 55 in a plan view.

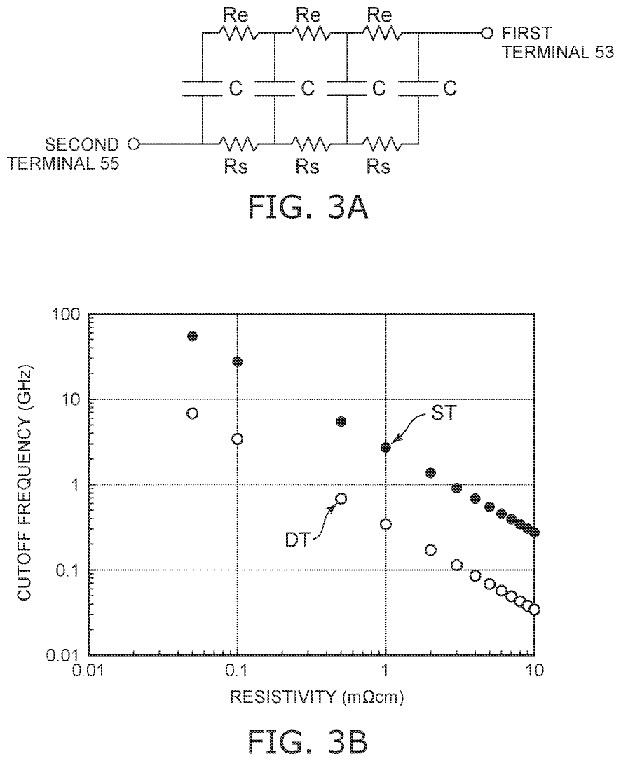

FIGS. 3A and 3B are schematic views showing characteristics of the capacitor 1 according to the embodiment. FIG. 3A is an equivalent circuit of the capacitor 1. FIG. 3B is a graph showing high-frequency characteristics of the capacitor 1.

As shown in FIG. 3A, the capacitor 1 includes substrate resistance Rs, a capacitance C provided inside a respective one of the multiple trenches TR, and resistance Re of the electrode layer 30. In the capacitor 1, by providing the capacitance C inside the multiple trenches TR, a static capacitance can be increased without increasing an area occupied at the surface 10F side of the semiconductor substrate 10. In other words, the capacitor 1 can be made smaller by providing the trench TR.

FIG. 3B is a graph showing a relationship between a cutoff frequency between the first terminal 53 and the second terminal 55 and resistivity of the electrode layer 30. A horizontal axis represents the resistivity, and a vertical axis represents the cutoff frequency. FIG. 3B shows characteristics of two samples DT and ST having trenches TR with different sizes.

In FIG. 3B, the substrate resistance Rs is constant. In the sample ST, the depth TD of the trench TR is 50 micrometers (μm), and the trench width TW is 2 μm. In the sample DT, the depth TD of the trench TR is 100 micrometers (μm), and the trench width TW is 1 μm.

The cutoff frequency decreases as the resistivity of the electrode layer 30 increases. When the trench TR becomes deeper, the cutoff frequency decreases. When the electrode layer 30 is a single layer of polysilicon, the resistivity is 10 mΩcm, and the cutoff frequency is 1 GHz or less.

In order to improve the cutoff frequency of the capacitor 1, it is favorable to reduce the resistivity of the electrode layer 30. In order to increase the static capacitance by increasing the depth TD of the trench TR, the resistivity of the electrode layer 30 is desirably reduced. Resistance of the electrode layer 30 is reduced by including the second conductive layer 35 containing a metal silicide. Accordingly, it is possible to increase a cutoff frequency of the capacitor 1.

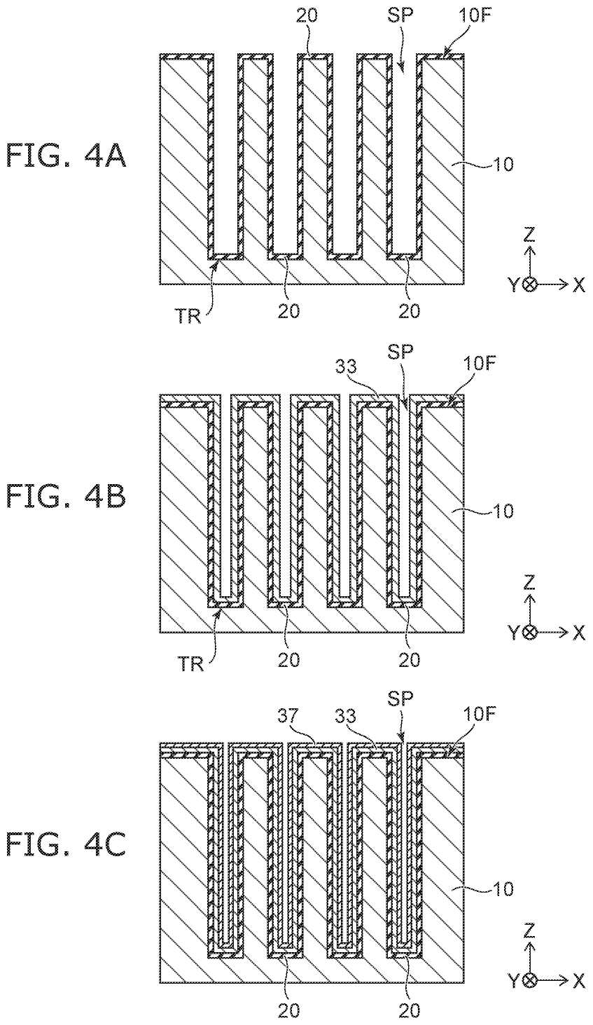

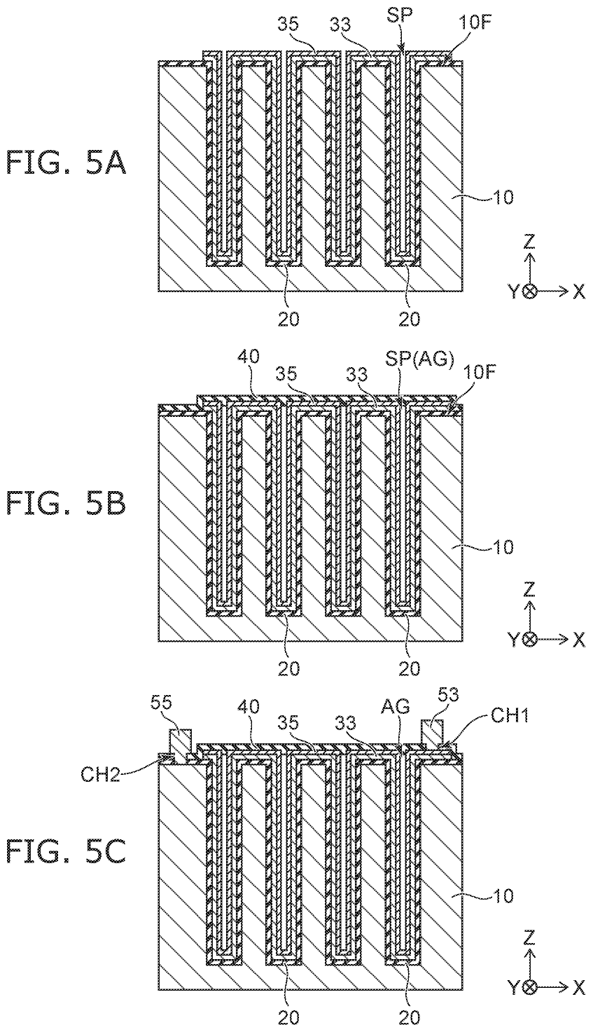

Next, a method for manufacturing the capacitor 1 will be described with reference to FIGS. 4A to 5C. FIGS. 4A to 5C are schematic cross-sectional views showing a process for manufacturing the capacitor 1 according to the embodiment.

As shown in FIG. 4A, multiple trenches TR are formed at the surface 10F side of the semiconductor substrate 10. The trench TR is provided by selectively removing the semiconductor substrate 10 using anisotropic reactive ion etching (RIE), for example.

Further, the dielectric film 20 is formed at the surface 10F side of the semiconductor substrate 10. The dielectric film 20 covers the inner surface of the trench TR. The dielectric film 20 is provided by, for example, thermally oxidizing or thermally nitriding the semiconductor substrate 10. In addition, the dielectric film 20 may be formed using chemical vapor deposition (CVD). The dielectric film 20 is formed to leave a space SP inside the trench TR.

As shown in FIG. 4B, the first conductive layer 33 is formed on the dielectric film 20. The first conductive layer 33 is a semiconductor layer containing silicon, for example, polysilicon. The first conductive layer 33 contains, for example, an n-type impurity or a p-type impurity. The first conductive layer 33 is formed using, for example, CVD. The first conductive layer 33 covers the surface 10F of the semiconductor substrate 10 via the dielectric film 20. The first conductive layer 33 covers the inner surface of the trench TR via the dielectric film 20. The first conductive layer 33 is formed to leave the space SP inside the trench TR.

As shown in FIG. 4C, a metal layer 37 is formed on the first conductive layer 33. The metal layer 37 covers the first conductive layer 33 at the surface 10F side of the semiconductor substrate 10 and inside the trench TR. The metal layer 37 is also formed to leave the space SP inside the trench TR.

The metal layer 37 is formed by, for example, a non-electroplating method after treating a surface of the first conductive layer 33 by a wet process using a noble metal catalyst, so-called MacEtch (see NPL 1). A plating layer can be more uniformly formed by metal atoms adhering to the surface of the first conductive layer 33 in the MacEtch process. Accordingly, the metal layer 37, for example, a nickel layer can be uniformly formed on the inner surface of the trench TR having a large aspect ratio TD/TW (see FIG. 1).

As shown in FIG. 5A, the second conductive layer 35 is formed on the first conductive layer 33. The second conductive layer 35 is formed, for example, after the first conductive layer 33 and the metal layer 37 are partially removed. That is, on the surface 10F of the semiconductor substrate 10, portions of the first conductive layer 33 and the metal layer 37 formed around the trench TR (see FIG. 2) are removed. The second conductive layer 35 is formed by reacting the first conductive layer 33 and the metal layer 37 by a heat treatment. That is, the second conductive layer 35 contains a metal silicide formed by a reaction of the first conductive layer 33 and the metal layer 37.

As shown in FIG. 5B, the insulating film 40 is formed at the surface 10F side of the semiconductor substrate 10. The insulating film 40 covers the second conductive layer 35 and closes an opening of the space SP in the trench TR. Accordingly, the gap AG is left inside the trench TR.

The insulating film 40 is formed using, for example, plasma enhanced chemical vapor deposition (PCVD). The insulating film 40 is, for example, a silicon nitride film. The insulating film 40 is also provided on a region around the trench TR (see FIG. 2) from which the first conductive layer 33 and the metal layer 37 are removed at the surface 10F side of the semiconductor substrate 10.

As shown in FIG. 5C, the first terminal 53 and the second terminal 55 are formed on the insulating film 40. The first terminal 53 is formed on the surface 10F of the semiconductor substrate 10 after the contact hole CH1 communicating with the second conductive layer 35 is formed in the insulating film 40. The second terminal 55 is formed on the surface 10F of the semiconductor substrate 10 after the contact hole CH2 communicating with the semiconductor substrate 10 is formed in the dielectric film 20 and the insulating film 40.

The first terminal 53 and the second terminal 55 are formed by patterning a metal layer, for example, an aluminum layer, formed on the insulating film 40. The first terminal 53 extends in the contact hole CH1 to be in contact with the second conductive layer 35, and is electrically connected to the second conductive layer 35. The second terminal 55 extends in the contact hole CH2 to be in contact with the semiconductor substrate 10, and is electrically connected to the semiconductor substrate 10.

In the method for manufacturing the capacitor 1 according to the embodiment, by leaving the space SP inside the trench TR, a stress in a process of forming the dielectric film 20, the first conductive layer 33, and the second conductive layer 35 can be relaxed, and warpage of the semiconductor substrate 10 can be prevented. Accordingly, a manufacturing yield can be improved.

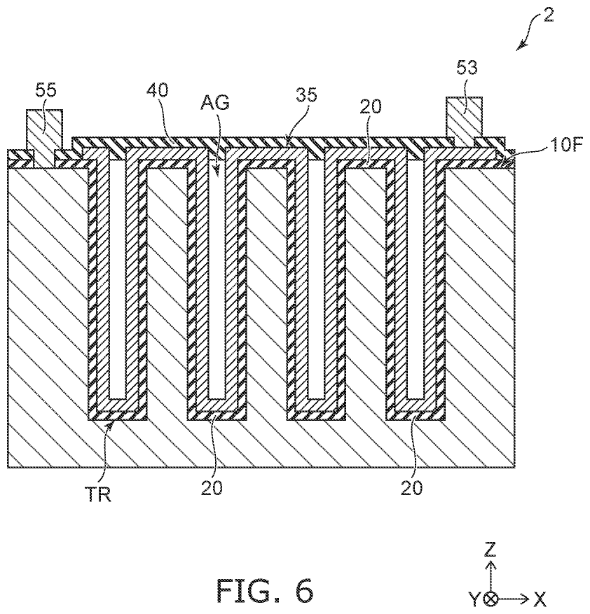

FIG. 6 is a schematic cross-sectional view showing a capacitor 2 according to a first variation of the embodiment. The capacitor 2 includes the semiconductor substrate 10, the dielectric film 20, the second conductive layer 35, the insulating film 40, the first terminal 53, and the second terminal 55.

In the capacitor 2, the electrode layer 30 (see FIG. 1) is replaced with the second conductive layer 35 as a single layer. That is, when the first conductive layer 33 is thin, the entire first conductive layer 33 reacts with the metal layer 37, and the electrode layer 30 becomes the second conductive layer 35 containing a metal silicide. The second conductive layer 35 containing a metal silicide faces the semiconductor substrate 10 via the dielectric film 20. Accordingly, the resistance Re (see FIG. 3) for the electrode layer can be further reduced, and the cutoff frequency can be increased.

The capacitor 2 is formed by, for example, thickening the metal layer 37. The metal layer 37 can be formed to have a desired thickness by, for example, combining a non-electroplating method and an electroplating method. In this example, the gap AG also extends from an opening in the second conductive layer 35 at the surface 10F side of the semiconductor substrate 10 to the vicinity of the lower end of the trench TR at the bottom surface side.

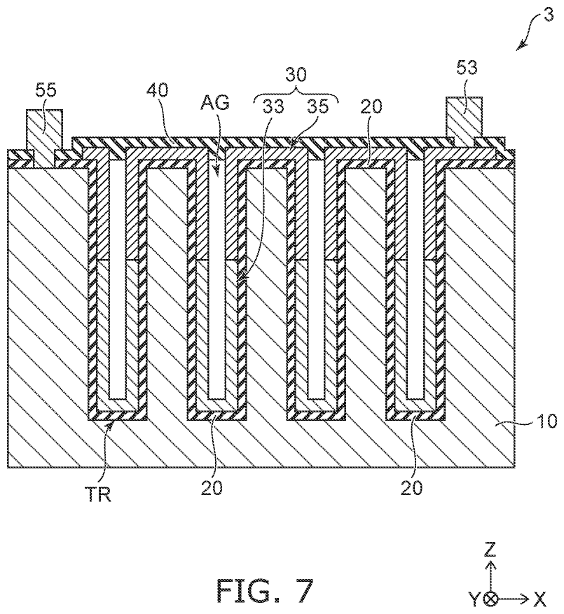

FIG. 7 is a schematic cross-sectional view showing a capacitor 3 according to a second variation of the embodiment. The capacitor 3 includes the semiconductor substrate 10, the dielectric film 20, the electrode layer 30, the insulating film 40, the first terminal 53, and the second terminal 55.

As shown in FIG. 7, the electrode layer 30 includes the first conductive layer 33 and the second conductive layer 35. The first conductive layer 33 is, for example, conductive polysilicon, and is provided on a bottom surface and a side wall at a bottom portion of the trench TR. The second conductive layer 35 is provided at an upper portion of the trench TR so as to be connected to the first conductive layer 33. The second conductive layer 35 contains a metal silicide.

For example, in the manufacturing process shown in FIG. 4C, when the metal layer 37 covers the upper portion of the trench TR without being formed up to the bottom portion of the trench TR, the second conductive layer 35 is not formed at the bottom portion of the trench TR, and the first conductive layer 33 remains at the bottom portion of the trench TR. When the first conductive layer 33 is thick, the first conductive layer 33 may remain between the dielectric film 20 and the second conductive layer 35 (see FIG. 1).

Even in such a structure, the resistance Re (see FIG. 3) of the electrode layer 30 is reduced by the second conductive layer 35. Accordingly, it is possible to increase the cutoff frequency of the capacitor 3. The gap AG extends from the opening of the second conductive layer 35 to a vicinity of a lower end of the first conductive layer 33. Accordingly, a stress in the semiconductor substrate 10 can be reduced.

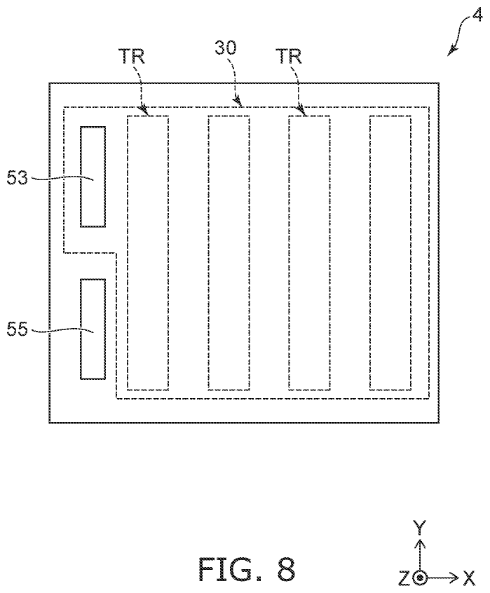

FIG. 8 is a schematic plan view showing a capacitor 4 according to a third variation of the embodiment. FIG. 8 shows the first terminal 53 and the second terminal 55 provided on the insulating film 40. The first terminal 53 is positioned on the electrode layer 30.

As shown in FIG. 8, the multiple trenches TR each extend in the Y-direction and are aligned in the X-direction. The first terminal 53 and the second terminal 55 are aligned in the Y-direction. The first terminal 53, the second terminal 55, and the multiple trenches TR are aligned in the X-direction. Accordingly, leads connected to the first terminal 53 and the second terminal 55 can be drawn out in the same direction.

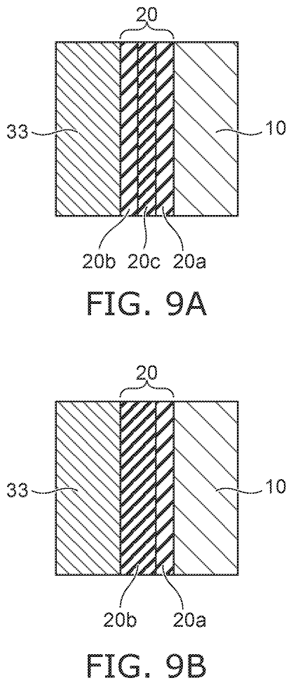

FIGS. 9A and 9B are schematic cross-sectional views showing the dielectric films 20 of the capacitors 1 to 3 according to the embodiment. The dielectric film 20 is not limited to a single-layer film, and may have a stacked structure including multiple films.

As shown in FIG. 9A, the dielectric film 20 includes a first film 20a, a second film 20b, and a third film 20c. Between the semiconductor substrate 10 and the first conductive layer 33, the third film 20c is provided between the first film 20a and the second film 20b. The first film 20a is provided between the semiconductor substrate 10 and the third film 20c. The second film 20b is provided between the first conductive film 33 and the third film 20c.

The first film 20a and the second film 20b are, for example, silicon oxide films. The third film 20c is, for example, a silicon nitride film. The third film 20c may be a high dielectric constant film of aluminum oxide, hafnium oxide or the like.

As shown in FIG. 9B, the dielectric film 20 includes the first film 20a and the second film 20b. The first film 20a is provided between the semiconductor substrate 10 and the second film 20b. The second film 20b is provided between the first conductive layer 33 and the first film 20a.

The first film 20a is, for example, a silicon oxide film. The second film 20b is, for example, a silicon nitride film. The second film 20b may be a high dielectric constant film of aluminum oxide, hafnium oxide or the likes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

### Note 1

A capacitor comprising:
a semiconductor substrate;
an electrode layer extending from a surface of the semiconductor substrate into the semiconductor substrate and containing a metal silicide in the semiconductor substrate;
a dielectric film provided between the electrode layer and the semiconductor substrate and electrically insulating the electrode layer from the semiconductor substrate;
a first terminal connected to the electrode layer; and
a second terminal connected to the semiconductor substrate.

### Note 2

The capacitor according to note 1, further comprising:
an insulating film covering the electrode layer at a surface side of the semiconductor substrate,
the electrode layer including an opening positioned at the surface side of the semiconductor substrate, and a gap extending from the opening to an end portion in the semiconductor substrate, and
the insulating film closing the opening of the electrode layer.

### Note 3

The capacitor according to note 2, wherein
the first terminal is provided on the insulating film and extends in a first contact hole provided in the insulating film so as to be connected to the electrode layer, and
the second terminal is provided on the insulating film and extends in a second contact hole provided in the insulating film so as to be connected to the semiconductor substrate.

### Note 4

The capacitor according to note 3, wherein
the insulating film covers the surface side of the semiconductor substrate,
the dielectric film extends between the semiconductor substrate and the insulating film,
the second contact hole penetrating the insulating film and the dielectric film and communicating with the semiconductor substrate is provided, and
the second terminal extends in the second contact hole so as to be connected to the semiconductor substrate.

### Note 5

The capacitor according to any one of notes 1 to 4, wherein
the electrode layer further includes a polysilicon layer provided between the dielectric film and the metal silicide.

### Note 6

The capacitor according to any one of notes 1 to 5, wherein
the dielectric film includes at least one of a silicon oxide film, a silicon nitride film, and a high dielectric constant film.

### Note 7

The capacitor according to any one of notes 1 to 6, wherein
the semiconductor substrate has a trench at a surface side,
the dielectric film covers a bottom surface and a side wall of the trench, and
the electrode layer covers the dielectric film on an inner surface of the trench.

### Note 8

The capacitor according to note 7, wherein
the electrode layer further contains conductive polysilicon,
the polysilicon is provided on the dielectric film on the bottom surface and at a bottom surface side of the side wall of the trench, and
the metal silicide is provided on the dielectric film at an opening side of the trench.

What is claimed is:

1. A capacitor comprising:
a semiconductor substrate;
an electrode layer extending from a surface of the semiconductor substrate into the semiconductor substrate and containing a metal silicide in the semiconductor substrate;
a dielectric film provided between the electrode layer and the semiconductor substrate and electrically insulating the electrode layer from the semiconductor substrate;
a first terminal connected to the electrode layer; and
a second terminal connected to the semiconductor substrate.

2. The capacitor according to claim 1, further comprising:
an insulating film covering the electrode layer at a surface side of the semiconductor substrate,
the electrode layer including an opening positioned at the surface side of the semiconductor substrate, and a gap extending from the opening to an end portion in the semiconductor substrate, and
the insulating film closing the opening of the electrode layer.

3. The capacitor according to claim 2, wherein
the first terminal is provided on the insulating film and extends in a first contact hole provided in the insulating film so as to be connected to the electrode layer, and
the second terminal is provided on the insulating film and extends in a second contact hole provided in the insulating film so as to be connected to the semiconductor substrate.

4. The capacitor according to claim 3, wherein
the insulating film covers the surface side of the semiconductor substrate,
the dielectric film extends between the semiconductor substrate and the insulating film,
the second contact hole penetrating the insulating film and the dielectric film and communicating with the semiconductor substrate is provided, and
the second terminal extends in the second contact hole so as to be connected to the semiconductor substrate.

5. The capacitor according to claim 1, wherein
the electrode layer further includes a polysilicon layer provided between the dielectric film and the metal silicide.

6. The capacitor according to claim 1, wherein
the dielectric film includes at least one of a silicon oxide film, a silicon nitride film, and a high dielectric constant film.

7. The capacitor according to claim 1, wherein
the semiconductor substrate has a trench at a surface side,
the dielectric film covers a bottom surface and a side wall of the trench, and
the electrode layer covers the dielectric film on an inner surface of the trench.

8. The capacitor according to claim 7, wherein
the electrode layer further contains conductive polysilicon,
the polysilicon is provided on the dielectric film on the bottom surface and at a bottom surface side of the side wall of the trench, and
the metal silicide is provided on the dielectric film at an opening side of the trench.
